(19) United States
(12) Patent Application Publication
(10) Pub. No.: US 2011/0254593 A1
(43) Pub. Date: Oct. 20, 2011

(54) POWER SUPPLY DRIVER CIRCUIT

(75) Inventor: HENG-CHEN KUO, Tu-Cheng (TW)

(73) Assignee: HON HAI PRECISION INDUSTRY CO., LTD., Tu-Cheng (TW)

(21) Appl. No.: 12/848,360

(22) Filed: Aug. 2, 2010

(30) Foreign Application Priority Data
Apr. 20, 2010 (TW) 99112413

(51) Int. Cl. H03K 3/00

(52) U.S. Cl. 327/108

(57) ABSTRACT

A power supply driver circuit for providing power to an electronic device includes a switch module, a voltage regulator and a driver module. The switch module receives a control signal and turns on according to the control signal. The voltage regulator receives a first voltage and outputs a second voltage when the switch module turns on. The driver module provides power to the electronic device when the driver module receives the second voltage.

### BACKGROUND

1. Technical Field

The present disclosure relates to a power supply driver circuit for point of sale (POS) terminal.

2. Description of Related Art

Point of sale (POS) terminal or cash register is the location where a sales transactions typically occur in a shop. A POS terminal manages the selling process by a salesperson with accessible interface. A Retail Point of Sales system typically includes cash drawer with various other components cooperating with a computer. Usually the cash drawer is driven by a 19V or 24V DC voltage from a computer. An electromagnet is disposed on the cash drawer. When the salesperson wants to open the drawer, the computer controls the DC voltage to provide power for the electromagnet via a switch circuit. The electromagnet then drives the cash drawer outwards from the cash register. However, the electromagnet needs to be powered up all the time in a typical cash register, which wastes power and increases the need for heat dissipation of the electromagnet.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block view of an embodiment of a power supply driver circuit for providing power to an electronic device.

FIG. 2 is a circuit view of the switch module and the voltage regulator module of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

In general, the word “module,” as used herein, refers to logic embodied in hardware or firmware, or to a collection of software instructions, written in a programming language, such as, for example, Java, C, or Assembly. One or more software instructions in the modules may be embedded in firmware, such as an EPROM. It will be appreciated that modules may comprise connected logic units, such as gates and flip-flops, and may comprise programmable units, such as programmable gate arrays or processors. The modules described herein may be implemented as either software and/or hardware modules and may be stored in any type of computer-readable medium or other computer storage device.

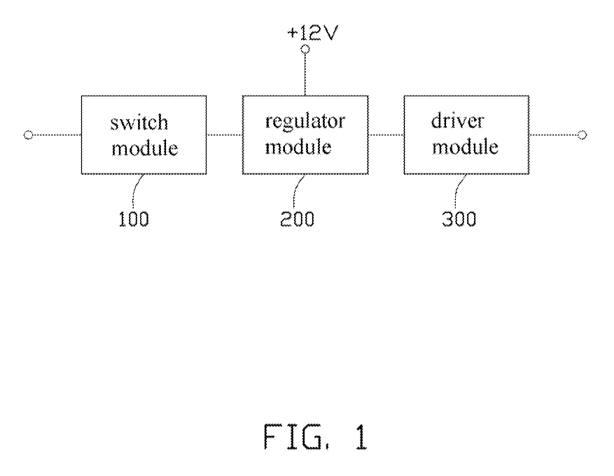

Referring to FIG. 1, a power supply driver circuit of an embodiment for providing power to an electronic device (not shown) includes a switch module 100, a voltage regulator module 200, and a driver module 300. The switch module 100 receives a control signal and turns on according to the control signal. The voltage regulator module 200 receives +12V and outputs +24V to the driver module 300 when the switch module 100 turns on. The driver module 300 is powered up and provides power to the electronic device when it receives the +24V.

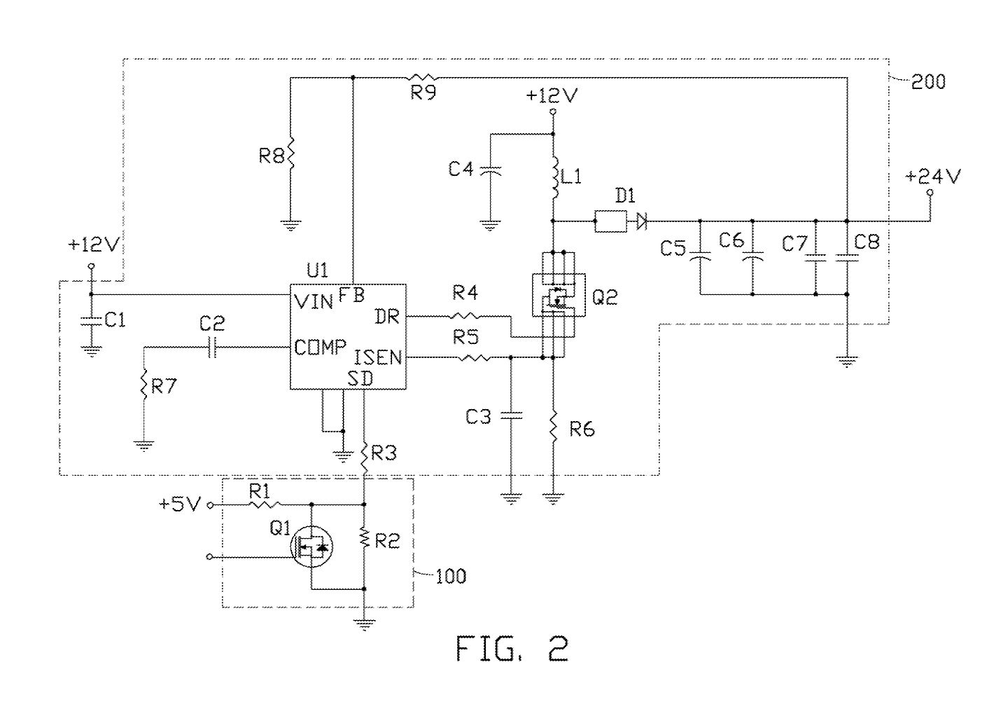

Referring to FIG. 2, the switch module 100 includes a MOSFET Q1 and resistors R1 and R2. A MOSFET Q1 grid receives the control signal. A MOSFET Q1 source is grounded. A MOSFET Q1 drain receives a +5V voltage via the resistor R1. The resistor R2 is electrically connected between the MOSFET Q1 source and drain. The voltage regulator module 200 includes a voltage transforming chip U1, a MOSFET Q2, a diode D1, an inductor L1, capacitors C1˜C8 and resistors R3˜R9. The voltage transforming chip U1 includes a control terminal SD, a driver terminal DR, a sensor terminal ISEN, a voltage input terminal VIN, a compensation terminal COPM and a feedback terminal FB. The control terminal SD is electrically connected to the MOSFET Q1 drain via the resistor R3. The driver terminal DR is electrically connected to a MOSFET Q2 grid via the resistor R4. The sensor terminal ISEN is electrically connected to a MOSFET Q2 source via the resistor R5. The MOSFET Q2 source is respectively grounded via the capacitor C3 and resistor R6. A MOSFET Q2 drain receives the +12V voltage via the inductor L1 and is electrically connected to a diode D1 anode. The voltage input terminal VIN receives the +12V voltage and is grounded via the capacitor C1. The compensation terminal COPM is grounded via the capacitor C2 and resistor R7 connected in series. The MOSFET Q2 drain is grounded via the inductor L1 and capacitor C4 which are connected in series. The feedback terminal FB is grounded via the resistor R8 and is electrically connected to a diode D1 cathode via the resistor R9. The diode D1 cathode is grounded via the capacitors C5˜C8 respectively and outputs +24V. In one embodiment, the voltage transforming chip U1 is a LM3488 type voltage regulator produced by National Semiconductor Company. The MOSFET Q1 is an N-channel MOSFET. The MOSFET Q2 is an N-channel power MOSFET. The diode D1 is a Schottky diode. The driver module 300 includes an electromagnet.

In use, when the electronic device needs to be powered up, the electronic device outputs a high voltage level control signal to the MOSFET Q1 grid. The MOSFET Q1 turns on and generates a low voltage level at the voltage transforming chip U1 control terminal SD. The voltage transforming chip U1 receives +12V at the voltage input terminal VIN and is powered up. The voltage transforming chip U1 outputs a high voltage level at the driver terminal DR. The MOSFET Q2 turns on. The +12V charges the inductor L1. When the inductor L1 is fully charged, the voltage transforming chip U1 outputs a low voltage level at the driver terminal DR. The MOSFET Q2 turns off and generates an inverse voltage on the inductor L1. The inductor L1 generates +24V at the diode D1 cathode. In one embodiment, the capacitors C5˜C8 are used to filter noise signals of the +24V.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A power supply driver circuit for providing power to an electronic device, comprising:
a switch module capable of receiving a control signal and turning on according to the control signal;
a voltage regulator capable of receiving a first voltage and outputting a second voltage when the switch module turns on; and
a driver module capable of providing power to the electronic device when the driver module receives the second voltage.

2. The power supply driver circuit of claim 1, wherein the switch module comprises a first MOSFET and a first resistor; a first MOSFET grid is capable of receiving the control signal; a first MOSFET source is grounded; and a first MOSFET drain is capable of receiving a third voltage via the first resistor.

3. The power supply driver circuit of claim 2, wherein the first voltage is +12V; the second voltage is +24V; and the third voltage is +5V.

4. The power supply driver circuit of claim 2, wherein the voltage regulator comprises a voltage transforming chip, a second MOSFET, a diode, a inductor, a third resistor and a fourth resistor; the voltage transforming chip comprises a control terminal, a driver terminal and a sensor terminal; the control terminal is electrically connected to the first MOSFET drain via the third resistor; the driver terminal is electrically connected to a second MOSFET grid; the sensor terminal is electrically connected to a second MOSFET source and is grounded via the fourth resistor; a second MOSFET drain is capable of receiving the first voltage via the inductor and is electrically connected to a diode anode; and a diode cathode is capable of outputting the second voltage.

5. The power supply driver circuit of claim 4, wherein the voltage regulator further comprises a voltage input terminal capable of receiving the first voltage.

6. The power supply driver circuit of claim 4, wherein the first MOSFET is a N-channel MOSFET; the second MOSFET is a N-channel power MOSFET; and the diode is a Schottky diode.

7. The power supply driver circuit of claim 6, wherein when the switch module receives a high voltage level control signal, the first MOSFET is capable of turning on and generating a low voltage level at the control terminal; and the voltage transforming chip is capable of being powered up and outputting a high voltage level at the driver terminal.

8. The power supply driver circuit of claim 7, wherein when the driver terminal outputs a high voltage level, the second MOSFET is capable of turning on; the first voltage is capable of charging the inductor; when the inductor is fully charged, the voltage transforming chip is capable of outputting a low voltage level at the driver terminal; the second MOSFET is capable of turning off and generating an inverse voltage on the inductor; and the inductor is capable of generating the second voltage at the diode cathode.

9. The power supply driver circuit of claim 8, wherein the driver module comprises an electromagnet.

10. A power supply driver circuit for providing power to an electronic device, comprising:
a switch module capable of receiving a control signal and turning on according to the control signal; the switch module comprising a first MOSFET;
a voltage regulator capable of receiving a first voltage and outputting a second voltage when the switch module turns on; the voltage regulator comprising a voltage transforming chip and a second MOSFET; and
a driver module capable of providing power to the electronic device when the driver module receives the second voltage; wherein when the switch module receives a high voltage level control signal, the first MOSFET is capable of turning on and outputting a low voltage level to the voltage transforming chip; the voltage transforming chip is capable of outputting a high voltage level; and the second MOSFET is capable of turning off and generating the second voltage.
